(19) United States
(12) Patent Application Publication
(10) Pub. No.: US 2012/0091336 A1
(43) Pub. Date: Apr. 19, 2012

(54) SEM ACTUATED LEVITATION DEVICES

(76) Inventors: Keng-Min Lin, San Mateo, CA (US); Ian Harvey, Kaysville, UT (US); Brian Baker, Salt Lake City, UT (US)

(21) Appl. No.: 13/272,851

(22) Filed: Oct. 13, 2011

Related U.S. Application Data
(60) Provisional application No. 61/393,002, filed on Oct. 14, 2010.

(51) Int. Cl. H01J 37/20; H01L 31/02

(52) U.S. Cl. 250/307; 257/429; 257/E31.11

(57) ABSTRACT

A microelectromechanical system (MEMS) device is configured to be actuated directly by an energy field through Coulombic interactions to have a translational motion. The MEMS device can be untethered, and actuated by irradiating an actuator with the energy field thereby building up electrical charges on the actuator. The MEMS device can thus be actuated with Coulomb forces from the built up electrical charges to suspend a movable portion over a rail. In one example, the energy field includes an electron beam from a scanning electron microscope (SEM).

### CROSS-REFERENCE TO RELATED APPLICATIONS

This application claims priority to U.S. Provisional Patent Application Ser. No. 61/393,002, filed Oct. 14, 2010, the disclosure of which is hereby incorporated by reference in its entirety.

### FIELD

The present disclosure is directed to micro electromechanical systems (MEMS), particularly actuation mechanisms of MEMS devices.

### BACKGROUND

Microsystems enable various kinds of designs into reality. For example, integrated circuits (ICs) make computations faster, and microfluidic chips allow measurements and experiments on minute amounts of samples. Miniaturizing systems also allows lower power consumptions, and more precise controls of movement.

MEMS structures, with typical dimensions ranging from a few microns to a millimeter, find a wide range of applications in, for example, variable capacitors, inductors, switches, sensors, gyroscopes, mirror devices, drug delivery devices, etc. Silicon is a widely used material for MEMS because of its superior mechanical properties, well developed processing technologies, and ease of integration with silicon-based ICs. Polymers and metals are also used for MEMS elements.

Actuating mechanisms can be an important aspect of a MEMS device. Conventional MEMS actuators are powered by electrical current generated by, for example, an electrical power source. The electrical current is directed to the MEMS actuators by an electrical current conduit composed of conductive materials such as metal or doped silicon. MEMS devices are actuated by the electrical current through electrostatic, piezoelectric, or resistive heating effects. In these conventional MEMS devices, a voltage or current power source is coupled to the actuator, typically by directly placing lead lines or probes onto the actuator to cause dynamic actuation thereto. These MEMS devices are thus tethered devices.

Magnetic levitation (maglev) vehicles use repulsive forces to float on rails. Hermann Kemper in Germany began the study of maglev system from 1930s. From the first passenger-carried maglev train in International Transportation Exhibition held in Hamburg in 1979, maglev vehicles have attracted a lot of attentions. Between 1984 and 1995, the first commercial automated maglev vehicle operated between Birmingham International Airport and Birmingham International Railway Station. At that time, the gap between the train and the rail was about 15 mm.

Levitation mechanisms in maglev vehicle systems include, for example, electromagnetic suspension (EMS), electrodynamic suspension (EDS), and magnetodynamic suspension (MDS) systems. An EMS system uses electromagnetic force to suspend and guide the vehicle. The difference in intensity of electromagnetic field between two ties attracts the vehicle above them to move the vehicle forward. The repulsive force between the ties and the vehicle is also used to support the vehicle. The EMS system has advantages in that it can work (float) at all speeds, unlike the EDS system in which the speed must exceed 30 km/hr. In the EDS system, the difference in magnetic field is used to support the system in which the vehicle and the rail are balanced naturally. Some MDS systems include magnetic levitation vehicle systems wherein permanent magnetic materials are used to create magnetic field between the rail and the vehicle.

### SUMMARY

In one aspect, a MEMS levitation device is provided including a movable portion and a track. The movable portion is configured to be actuated directly by an energy field through Coulombic interactions to have a translational motion over the track.

The translational motion can include at least one of a linear motion or a circular motion.

In one embodiment, the movable portion is configured to be suspended over the track by the Coulombic interactions during the translational motion.

In one embodiment, the device further includes a charge collection element coupled to the track and configured to build up electrical charges by directly interacting with the energy field. The energy field can interact with the actuator through free space propagation. The movable portion can be untethered.

The energy field can include at least one of an electron beam, a laser beam, a radiation beam, a charged particle beam, an uncharged particle beam, a photon beam, a static charge from triboelectric effect, or a discharge of a capacitor. For example, the energy field can include an electron beam from a scanning electron microscope (SEM).

In one embodiment, the MEMS device is configured as a carrying device or a sensor.

In one embodiment, the movable portion substantially encloses at least a portion of the track to thereby prevent the movable portion from derailing from the track. The movable portion can be configured to be levitated over the track and actuated through positive and negative charges generated from the energy field.

In one embodiment, the movable portion comprises a plurality of carriages, wherein at least one carriage is configured to be actuated to have the translational motion while at least another carriage is configured to contact the track to balance an electrical potential.

In another embodiment, the track substantially encloses at least a portion of the movable portion to thereby prevent the movable portion from derailing from the track. The movable portion can be configured to be both levitated over the track and actuated only through negative charges generated from the energy field.

In one embodiment, at least a portion of the movable portion and a portion of the track have smoothed surfaces to avoid the movable portion being stuck with the track. The smoothed surfaces can include substantially circular shapes.

In another aspect, a levitation system is provided including a microelectromechanical system (MEMS) device, which includes a train and a track. The train is not tethered to the track. The system further includes an SEM, which is configured, using an electron beam, to directly levitate the train over the track and actuate the train to have a translational motion about the track through Coulombic interactions.

In one embodiment, the MEMS device further includes a plurality of charge collection elements configured to generate electrical charges when illuminated with the electron beam to realize the Coulombic interactions between the train and the track.

In one embodiment, the train and the track include a first geometric shape configured to prevent the train from derailing from the track, and a second geometric shape configured to prevent the train from becoming stuck with the track.

In another aspect, a method of actuating a MEMS device is provided. The method includes irradiating an actuator of the MEMS device with an electron beam from an SEM thereby building up electrical charges on the actuator, and actuating the MEMS device with Coulomb forces from the built up electrical charges to suspend a movable portion over a rail and drive the movable portion along the rail in a translational motion.

In one embodiment, the actuating includes raster-scanning a portion of the rail.

In one embodiment, the method further includes observing the translational motion using the SEM at the same time of said actuating.

### BRIEF DESCRIPTION OF THE DRAWINGS

FIG. 1 is a schematic diagram illustrating the origin of two sources of secondary electron generation in a sample.

FIG. 2 is a plot illustrating penetration depths of incident electrons in polysilicon as a function of scanning electron microscope (SEM) accelerating voltages.

FIG. 3 is a cross-sectional view of a device structure designed using the SUMMiT™ V.

FIG. 4 is a perspective view of ellipse dimples at the bottom of the train device.

FIG. 5(a) is a schematic diagram of an electrostatic microfan-shaped device actuated by an SEM.

FIG. 5(b) is an SEM picture of the microfan-shaped device.

FIG. 6(a) is a top plan view of asymmetry alignment of trains on I-beam ties. Positions A, B, C and D indicate different asymmetry alignment between the Trains A, B, C, D and the ties.

FIG. 6(b) is a top plan view of asymmetry alignment of trains on I-beam ties.

FIG. 7(a) illustrates a COMSOL simulation of step 1 in levitation trains.

FIG. 7(b) illustrates a COMSOL cross-sectional line of electrical field in step 1.

FIG. 7(c) illustrates a COMSOL simulation of step 2 in levitation trains.

FIG. 7(d) illustrates a COMSOL cross-sectional line of electrical field in step 2.

FIG. 7(e) illustrates a COMSOL simulation of step 3 in levitation trains.

FIG. 7(f) illustrates a COMSOL cross-sectional line of electrical field in step 3.

FIG. 7(g) illustrates a COMSOL simulation of asymmetry in step 1 to step 4.

FIG. 8 is a cross-sectional view of positive charging plates.

FIG. 9(a) is an isometric view of the I-beam levitation train.

FIG. 9(b) is a top plan view of the I-beam levitation train.

FIG. 9(c) is a front view of the I-beam levitation train.

FIG. 9(d) is an isometric view of one tie in a 1 mm I-beam levitation train.

FIG. 9(e) is an SEM image of the I-beam levitation train system.

FIG. 9(f) is an SEM image of an I-beam levitation train system including a multi-car train 906.

FIG. 9(g) is an SEM image of an I-beam levitation train system including a train having a plurality of cars suspended on I-beam ties arranged in a circular configuration.

FIG. 10(a) is a front view of one tie in a 1 mm I-beam levitation train system.

FIG. 10(b) is a front view of the train on the tie in the 1 mm I-beam levitation train system.

FIG. 11(a) is a top plan view of the I-beam tie in a circular loop.

FIG. 11(b) is a cross-sectional view of the train with I-beam ties disposed in a circular loop. Positive charging plates are not shown in a complete view since the cross-sectional line is not parrelel to the arangement of the positive charging plates.

FIG. 12 is a cross-sectional view of a levitation platform.

FIG. 13 is a top plan view of the levitation platform.

FIG. 14(a) is a top plan view of the electrostatic microfan levitation train.

FIG. 14(b) is a front view of the electrostatic microfan levitation train.

FIG. 14(c) is an isometric view of the electrostatic microfan levitation train.

FIG. 14(d) is an SEM image of the electrostatic microfan levitation train.

FIG. 15(a) is a top plan view of the electrostatic microfan levitation train in a circular loop of ties.

FIG. 15(b) is an SEM image of the electrostatic microfan levitation train in a circular loop of ties.

FIG. 16(a) is an SEM image of a single-car I-beam levitation train in an misaligned position.

FIG. 16(b) is a schematic diagram of an I-beam levitation train system including smoothed edged portions configured to avoid the train being stuck on the track.

### DETAILED DESCRIPTION

### Introduction

In some representative embodiments, electrostatic forces generated by an SEM are used to suspend and actuate a MEMS device. Coulombic repulsive and/or attractive forces can be used for operating the levitation systems. In one embodiment, an “I-beam” tie system is provided, which uses both negative and positive charging from the SEM. In another embodiment, an electrostatic “microfan” system is provided using only negative charging from the SEM.

Charge Pumping Effect of the SEM

Embodiments disclosed herein provide a MEMS device, preferably fabricated on a silicon wafer substrate employing an actuating mechanism exploiting an energy field. One example of such an energy field is an electron beam. In one embodiment, MEMS devices are provided for harnessing the electron beam energy field for actuation thereof. The source of the electron beam can be an SEM.

In some representative embodiments, a MEMS device is provided that is activated, i.e., actuated, when subjected to a non-direct-contact pathway such as an energy field. The resulting MEMS device can be an untethered device. The energy field may propagate from its source to the MEMS device via free space, e.g., vacuum or air. The energy field can also be generated through electrical contacts to a source of open circuit static charge. One example form of energy field suitable for use with the MEMS device is an electron beam derived from an SEM. The electron beam can produce high static forces from injected or induced charging of the MEMS device. The charging results from structures of the MEMS device designed to be either primary electron traps (that develop a net negative static charge when subjected to the electron beam) or secondary-electron emitters (that develop a net positive static charge when subjected to the electron beam). The strength of the net negative static charge and the net positive static charge for a primary electron trap and a secondary-electron emitter, respectively, is influenced by accelerating voltage of the electron beam impacting the charge collection elements. The rate of charging induced by such an electron beam can be adjusted by adjusting the probe current of the SEM.

The electron beam created by the SEM, while under vacuum, is sufficiently energetic to impart a static charge differential upon the primary electron trap and the secondary-electron emitter of the MEMS device with such a magnitude that the device may be charged to, for example, thousands of volts. By using the electron beam energy field, the MEMS device may be “remotely” actuated in an untethered mode. The actuation occurs while the MEMS device is in the SEM that allows for visual, e.g., real-time, verification through concurrent imaging by standard SEM processes. Thus, it can be examined concurrently whether a desired effect has been achieved in the MEMS device while the MEMS device is being actuated.

A MEMS device being actuated when exposed to an electron beam energy field, for example, and without limitation, enables actuation of a controlled environment wherein the MEMS device drives the engagement or disengagement of a door, a gate, a switch, or other mechanisms to control exposure to a subject specimen. The MEMS device may provide a condition-specific actuation for enabling protection of the subject specimen until the right vacuum or sample conditions are achieved.

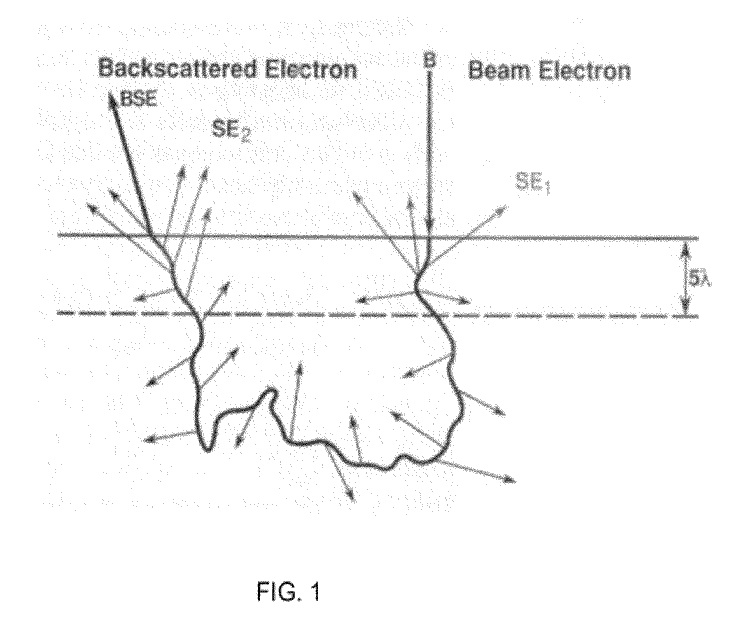

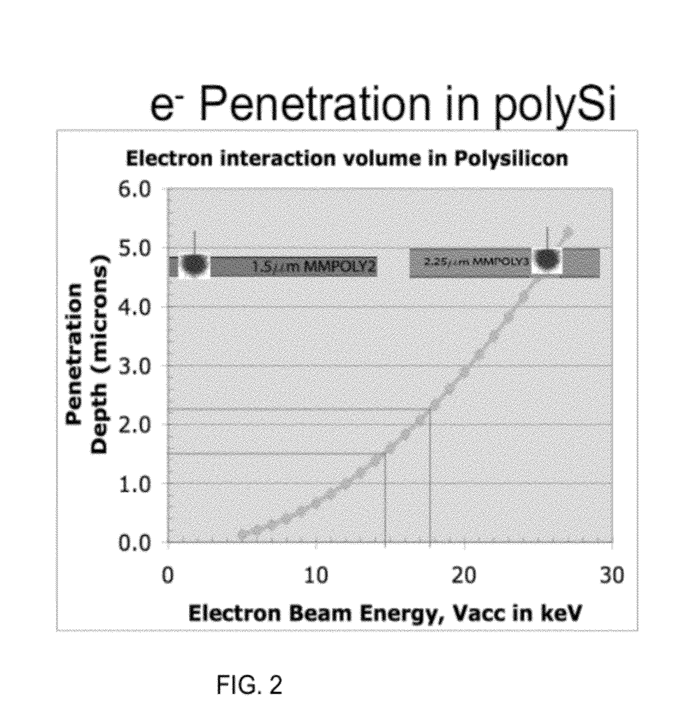

An SEM can use signals from samples to translate into image and chemical composition analyses. These signals include backscattered electrons (BSE), secondary electrons (SE), X-rays, etc. With reference to FIG. 1, when incident electrons from the SEM bombard a sample, secondary electrons (SE1) can be generated near the entrance of the electrons, and BSE and SE2 can be generated near the exit location of the incident electrons. The reaction area of BSE, SE1, and SE2 in the sample may be referred to as an interaction volume, and BSE is the main contributor for defining the interaction volume. For polysilicon, the depth of penetration of the BSE is shown in FIG. 2.

Those of ordinary skill in the art will recognize that such a MEMS device may be realized using existing fabrication processes, including standard IC fabrication processes. An example process for fabricating the devices uses physical and chemical deposition, photolithographic patterning, and both dry and wet etching to create mechanically-independent layers separated by sacrificial layers in surface-micromachined MEMS structures.

Although the energy field used to actuate the MEMS devices in accordance with some embodiments are described using an SEM electron beam as an example, those of ordinary skill in the art will recognize that other types and shapes of energy field can be utilized in actuating MEMS devices. For example, an electron flood gun, which “illuminates” a large area of a chip with electrons instead of a relatively narrow beam from an SEM, may be used to activate an array of devices collectively, either in chip form or in wafer form.

Other types of energy field may be used. A radiation beam of gamma rays, an electromagnetic wave (photon) beam such as a beam of UV light, a laser beam, and a beam of charged or uncharged particles or a mixing thereof from an accelerator, are also examples of an energy field that can be used to actuate MEMS devices in accordance with some embodiments. Example of charged particle beams include, for example, a particles, protons, a focused ion beam (FIB) such as a focused gallium (Ga) ion beam. In addition, a static charge from triboelectric effect, and a discharge of a capacitor may also be utilized. The energy field may either directly supply charged particles to the actuator as in an ionized particle or electron flux or beam, or it may be of sufficient intrinsic energy to ionize the material of the actuator to charge collection element such that electrons are extracted from the material, leaving it in net electron deficit (or net positive charge).

When other energy beams are used in place of an electron beam, the shape and the volume of the secondary electron generation region may be different. The minimum energy is what is necessary to liberate an electron from the material, to escape into free space. Although the phrase “beam” is often used in describing the energy field in the description, those of ordinary skill in the art will recognize that the energy field may not necessarily have a “beam” shape. For example, the beam may be focused, unfocused, collimated, or dispersed. An electromagnetic field of any shape or spatiotemporal distribution may be used to induce charge accumulations on the charge collection elements.

Dimensions of the material may be engineered to achieve a positive charging element or a negative charging element. For example, a length, a width, or a thickness, or a combination thereof, of a layer of material may be designed to be smaller than the interaction volume and, as a result, many secondary electrons will escape material layer, resulting in the element being positively charged. On the other hand, a material layer having a larger dimension can substantially enclose the interaction volume. Thus, almost all of the secondary electrons may be retained, resulting in a negatively charged element.

By engineering thicknesses, materials, geometry/topography, and coating of the layers, optimal differential charging of elements in a MEMS actuator can be realized. For example, an element can be designed to be either primary electron traps (net negative static charge) or efficient secondary electron emitters (net positive static charge), for a given energy field (such as an SEM with a specified accelerating voltage). Both repulsive and attractive Coulombic interactions can be achieved and utilized to actuate the MEMS devices.

A device charging region can be positively or negatively charged by changing the thickness of the charging region. For example, when a 15 keV accelerating voltage is used, based on FIG. 2, the penetration depth of electrons will be about 1.6 microns. Therefore, incident electrons can penetrate a one-micron-thick “polysilicon 1” layer, but cannot penetrate a “polysilicon 3” layer with a thickness of 2.25 microns. For the former one, a ground plate can be disposed beneath the thin “polysilicon 1” layer to collect the electrons expelled from the “polysilicon 1” layer, and this “polysilicon 1” layer will be positively charged. In the latter case, incident electrons remain in the “polysilicon 3” layer, thereby negatively charging this layer.

Device Designs

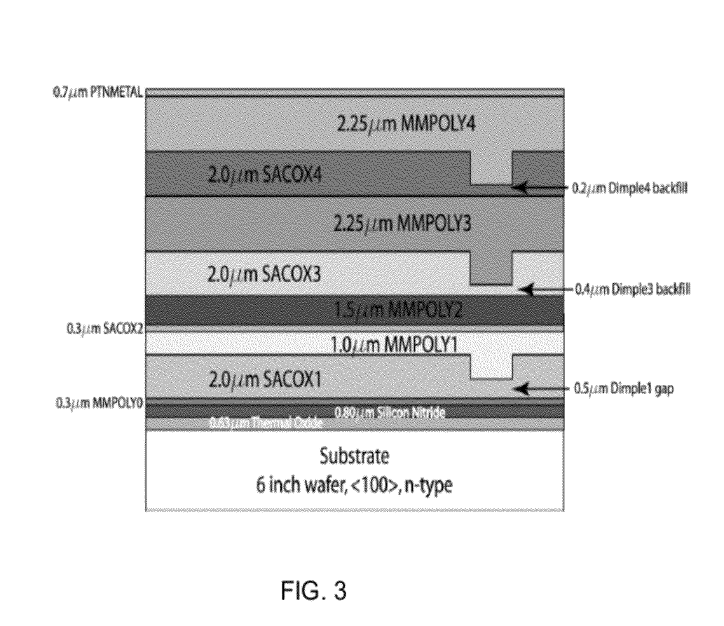

In some embodiments, an “I-beam tie” or an “electrostatic microfan” is used to suspend and actuate the levitation systems. SEM charging effects can be employed to actuate both systems and move the device in a translational and/or rotational motion. In the drawings, the direction from left to right may be referred to as “forward,” and the direction from right to left may be referred to as “backward.” Sandia Summit V is used to design and visualize this project, and COMSOL is used to simulate the electrical field generated by SEM. FIG. 3 is a layer layout of Sandia Summit V showing the thickness of each layers.

A levitation system can comprise a suspension movable portion, such as the train, and a base such as the rail that includes the I-beam ties. The train can be used to deliver an agent, such as a fluid, to a desired location. The train can also act as a sensor to sense properties, such as the strength, of the electron beam.

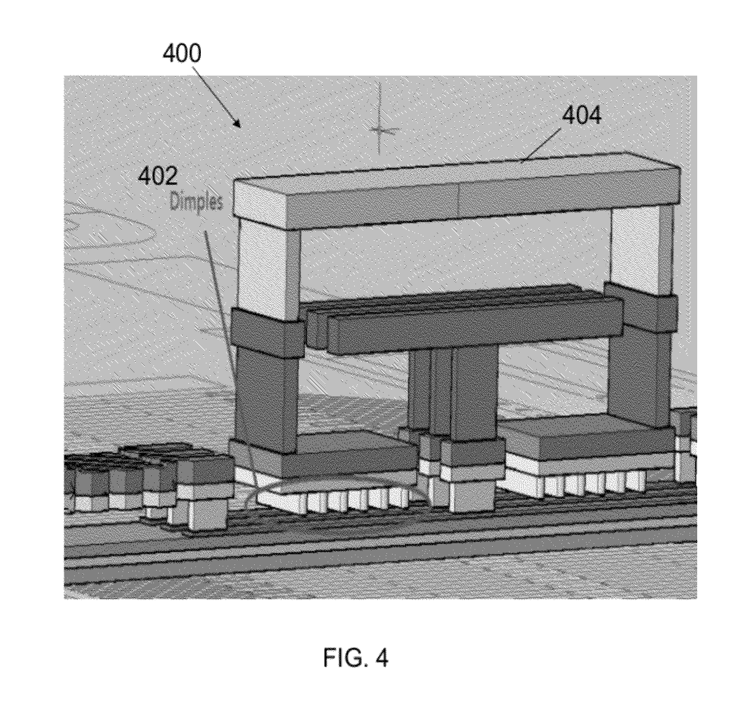

Dimples and/or protrusions can be disposed on the devices to balance the electrical potential between trains and ties. The dimples can also decrease contact areas between two adjacent polysilicon layers in fabrication processes. In the train system 400 shown in FIG. 4, dimples 402 at the bottom portion of the train 404 can balance electrical potentials from the train to the tie in each step. Since these dimples are perpendicular to the ties below them, a shape of an ellipse can prevent them from getting stuck in the ties. Other shapes can also be used. In this illustrative example, the dimples are about 1.5 microns tall and comprise “polysilicon 1” layer, as shown in FIG. 3.

The train 404 in this example embodiment substantially encloses portions 406 of the track, and forms a shape resembling a symbol “Ω.” By substantially enclosing at least a portion of the track, the train has a reduced probability of derailing.

Asymmetry in Electrostatic Microfan

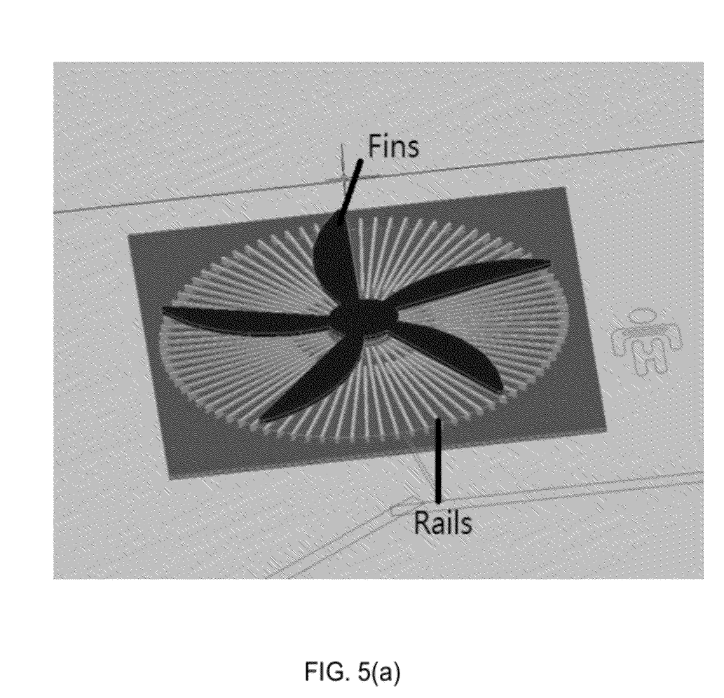

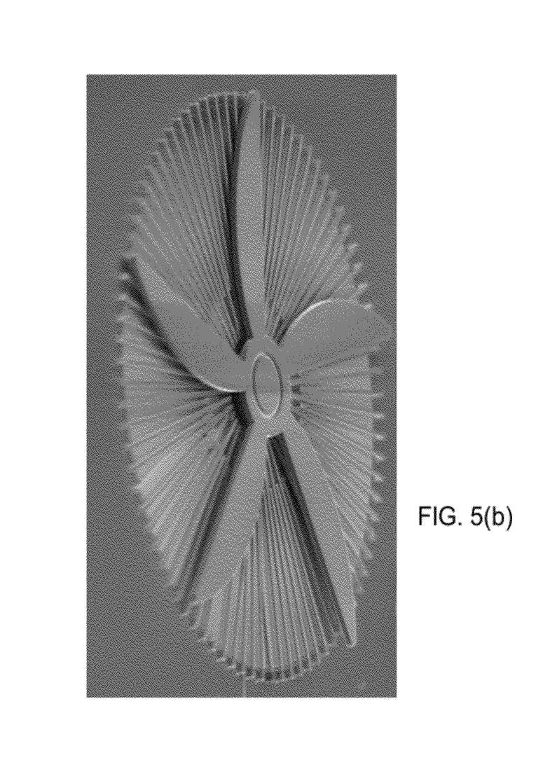

Asymmetry alignment of two layers of structures can produce different electrical fields when the charging effect occurs. FIGS. 5(a) and 5(b) show an electrostatic microfan in which five fins are not matched to the rails. Since each of them is at a different position with respect to the rails below it, there is at least one fin moves forward while some of them remain in electrical balance. Net force of the fins is always above zero and therefore the fins can rotate. This concept is reminiscent of four-cycle piston engine in which at least one piston is igniting while others are in different steps.

The microfan system illustrated in FIGS. 5(a) and 5(b) include an axis about which the fins rotate. However, as described in detail below, systems without an axis, particularly those with rail portions that are more laterally extended than the moving portions (e.g., trains, or fins), may also be referred to as “microfan systems.”

Asymmetry in Levitation Trains

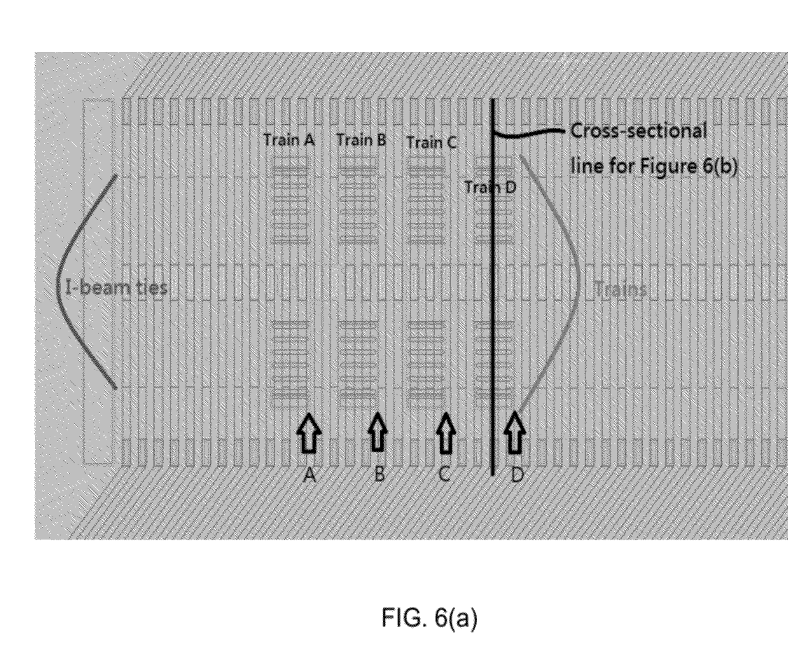

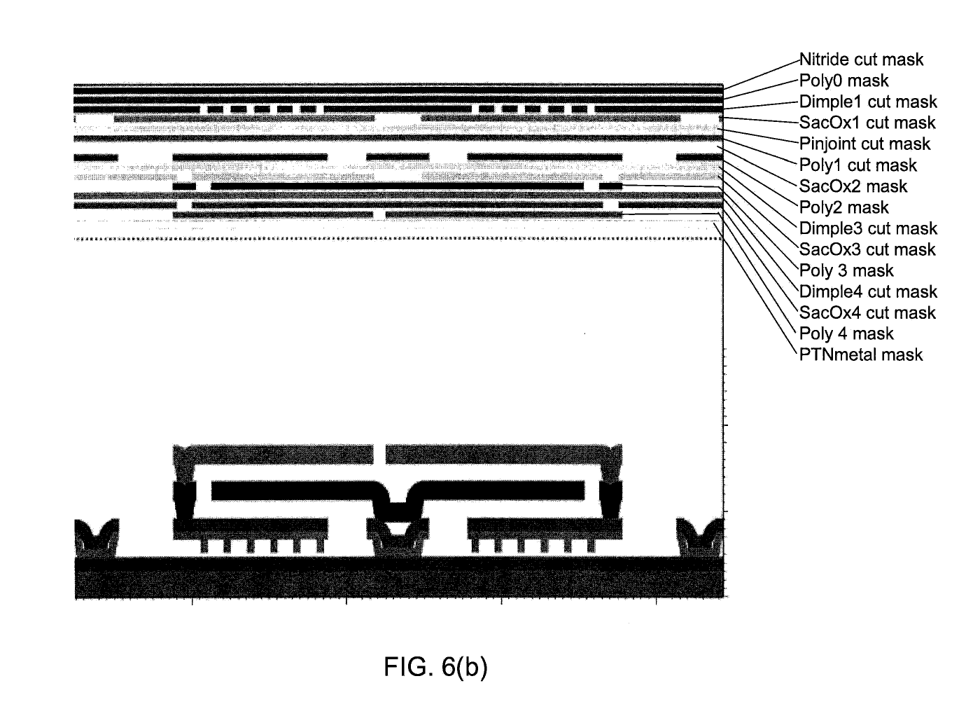

Asymmetric alignment can be adopted in the levitation trains to use different electrical potentials the asymmetric alignment generates to actuate the trains. FIGS. 6(a) and 6(b) are views from different angles of I-beam levitation train systems. Four train carriages or cars (Trains A, B, C and D in FIG. 6(a)) are connected into one levitation train. Different alignment of train on the tie enables at least one train car moves forward while some of the other train cars are in contact with the ties to balance the electrical potential.

Moving Mechanism of Levitation Trains

In one embodiment, the moving mechanism may include a number of operations such as:

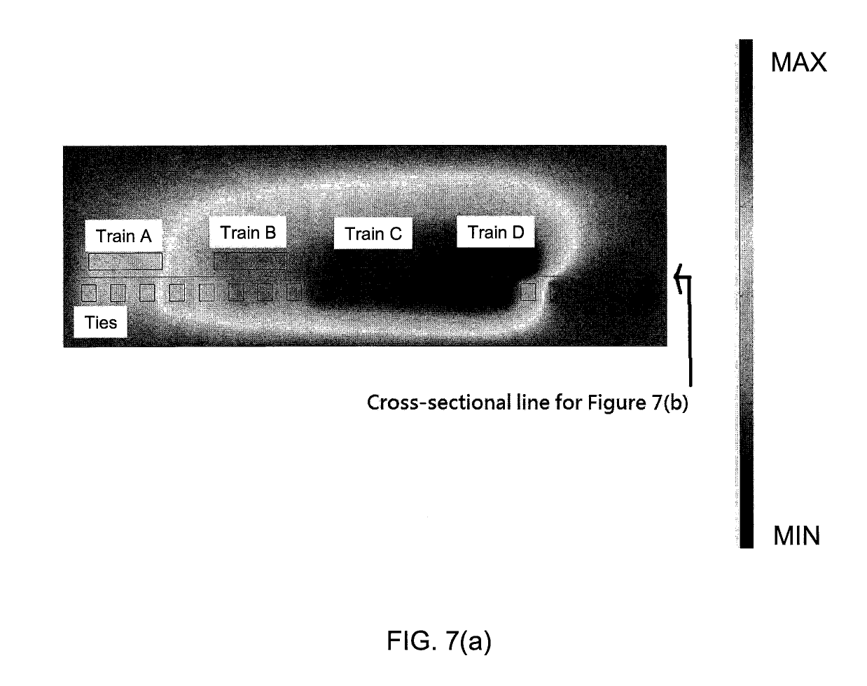

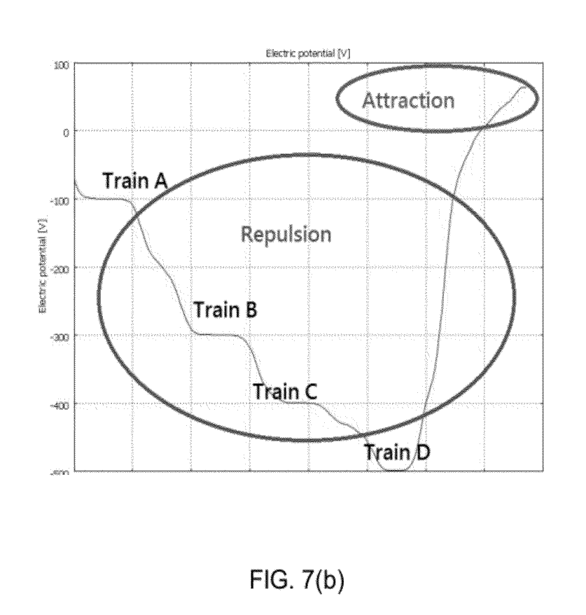

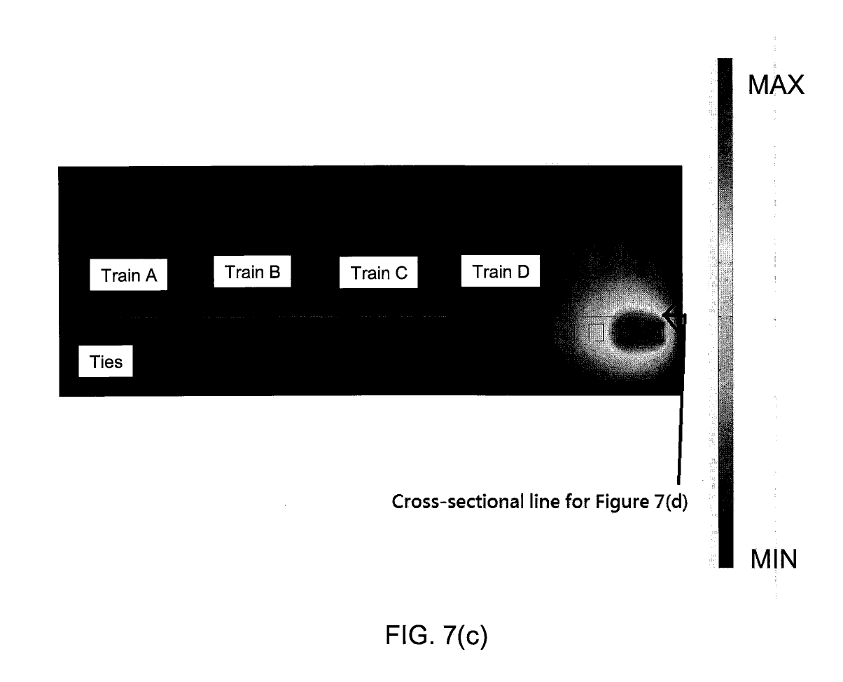

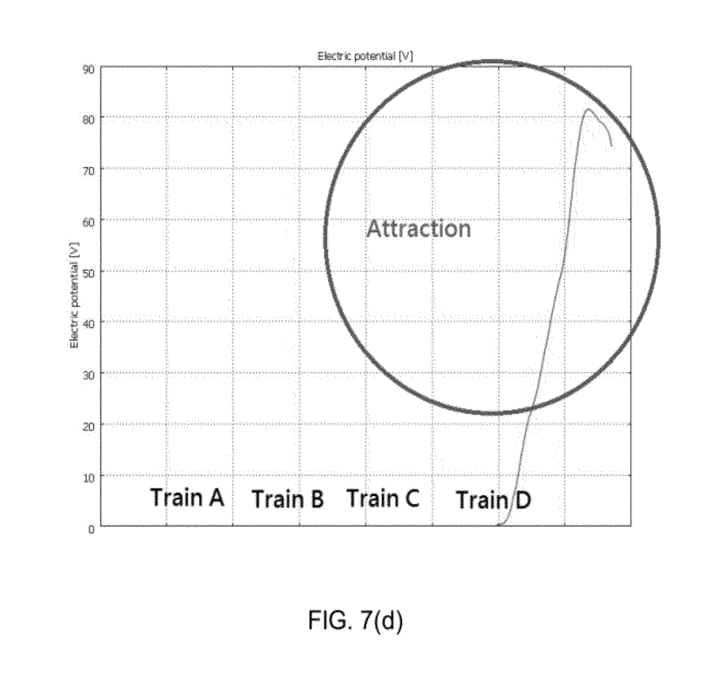

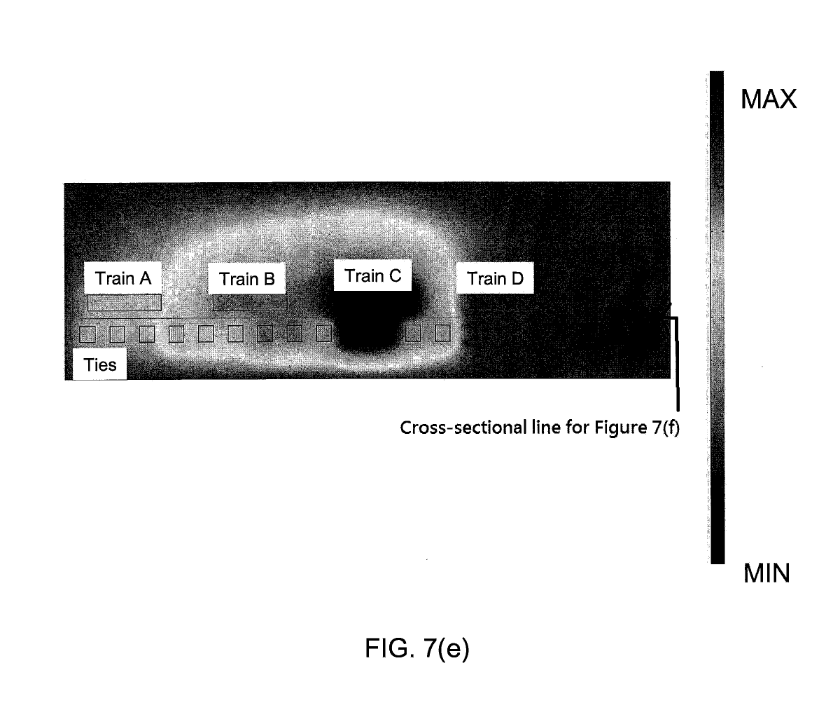

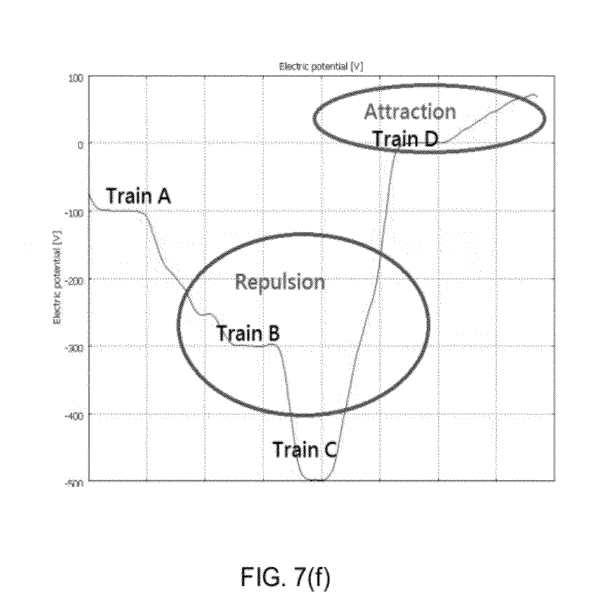

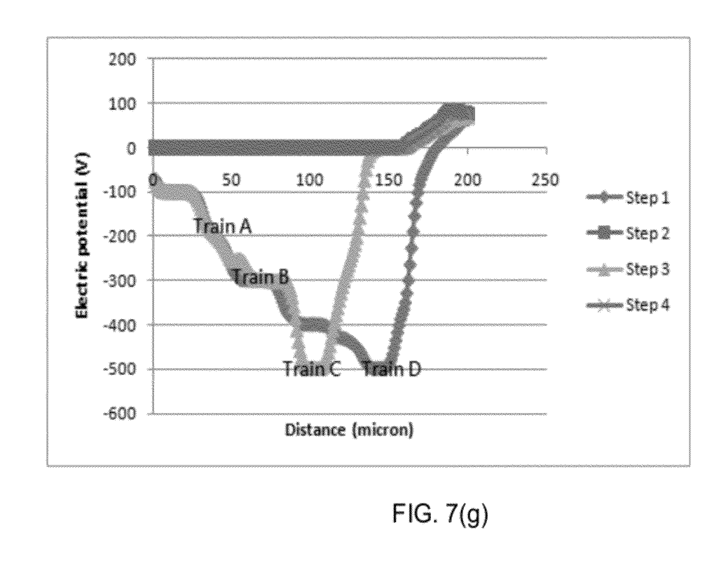

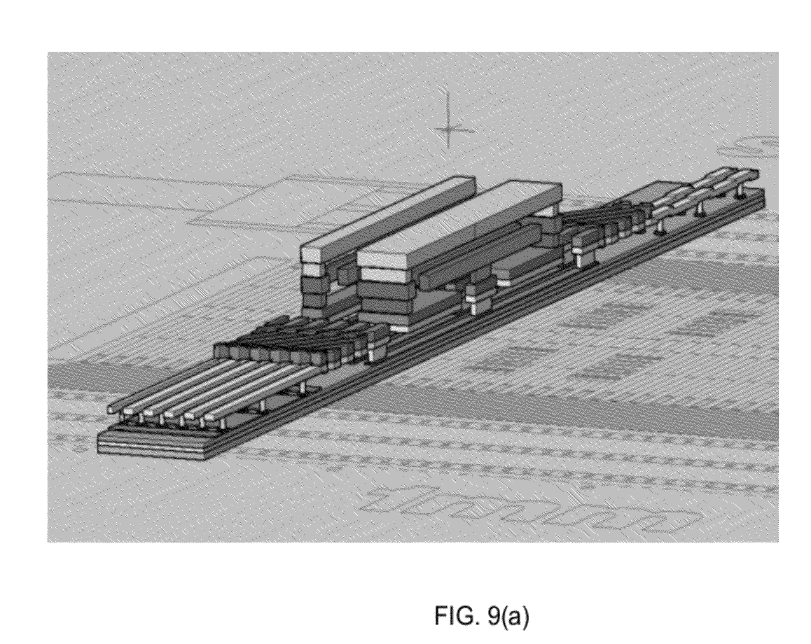

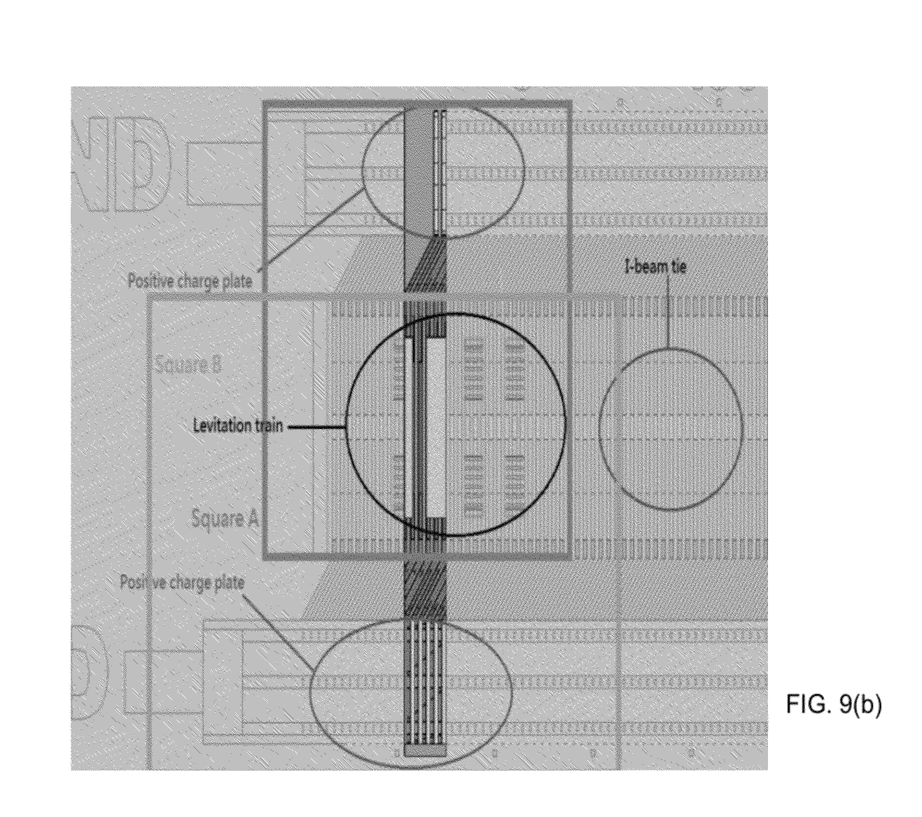

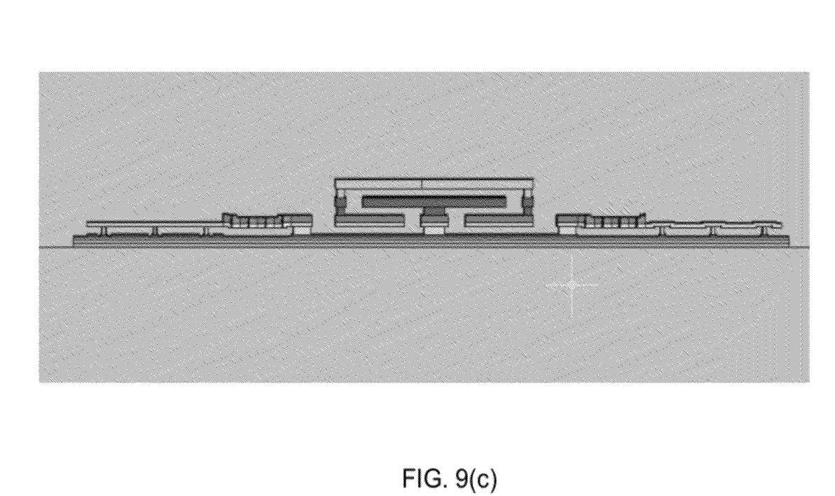

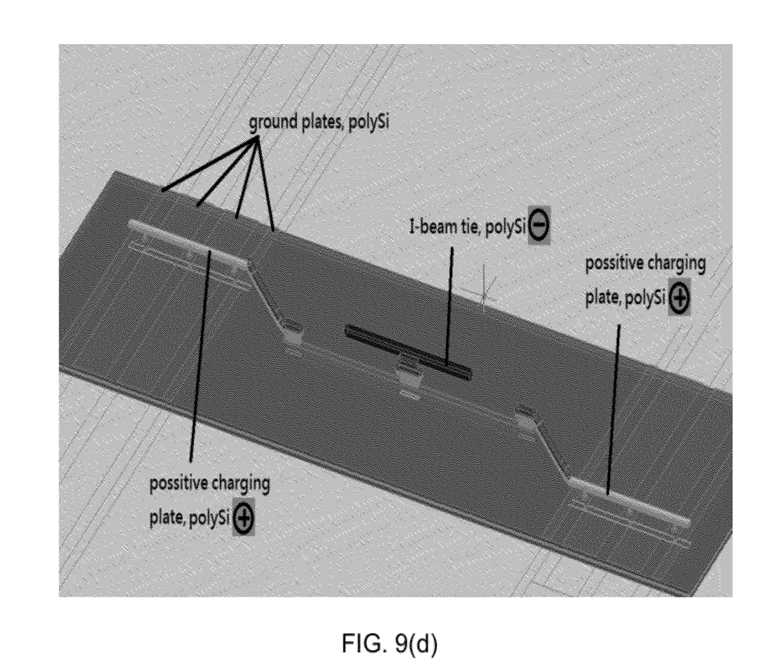

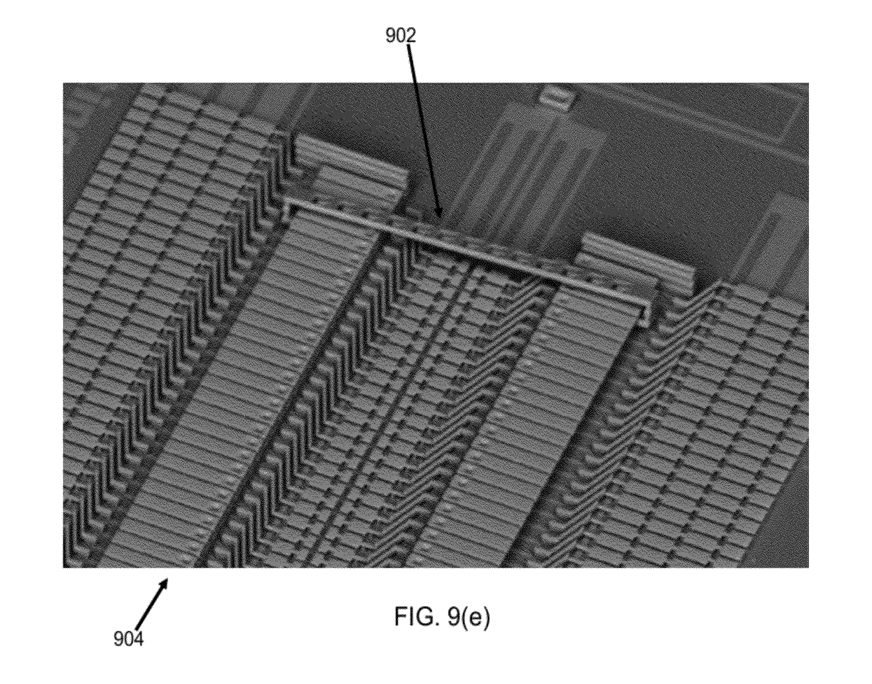

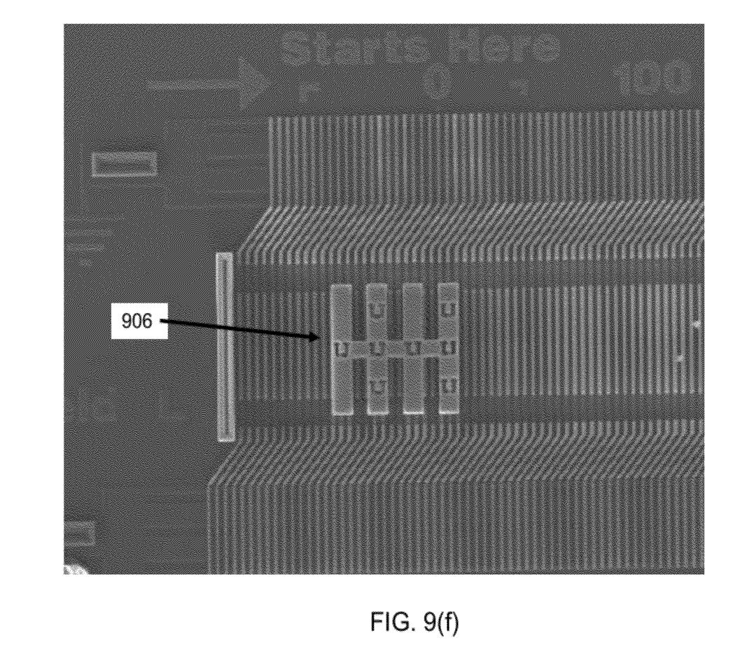

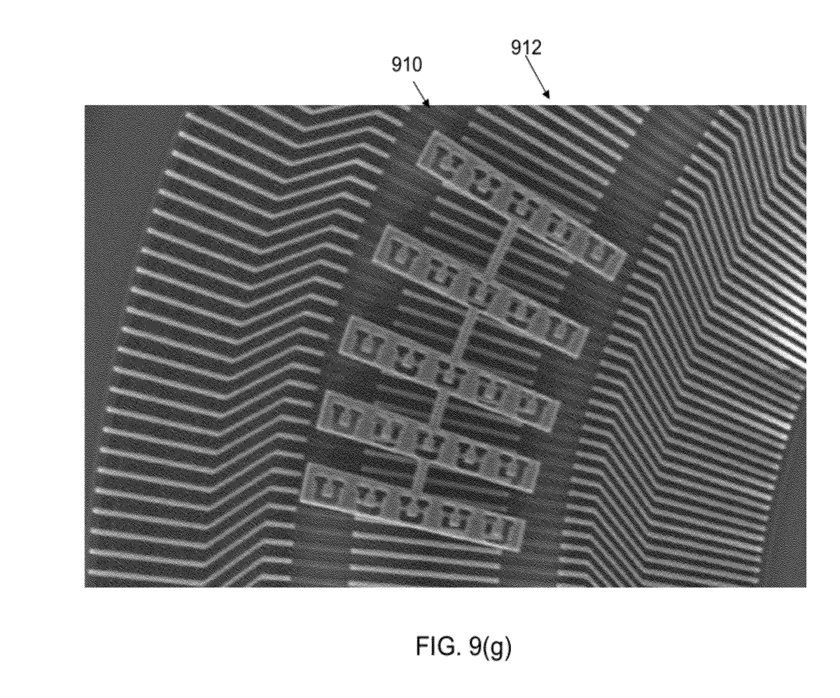

Step 1: Trains A, B, C and D in FIG. 6 (a) touch the I-beam ties at the beginning. In one example, an accelerating voltage between 12 and 18 keV is used to scan the raster area A in FIG. 9 (b) to produce negative charging effect at all the trains and ties below them, and positive charging effect at the charging plates in front of the Train D. This can produce −500 V at Train D area with +100 V at the ties in front of Train D, as shown in FIG. 7(a). FIG. 7 (b) shows the electrical potential in all of the trains in step 1. The charging plates can have other shapes, and are thus generally referred to as charging elements. These charging elements can be considered as an actuator of the levitation system.

Step 2: Once the +100V ties in front of Train D attract Train D to move forward, ellipse dimples at the bottom of Train D will contact the ties and balance the difference in electrical potentials between Train D and the ties.

Step 3: At this time, Trains A, B and C and the ties below them will be negatively charged. In addition, the ties in front of Train D will be positively charged to +100V. Therefore, the train is suspended again by repulsion between the area of Trains A, B and C as well as attraction between Train D and the ties in front of it. The train will move forward again.

Step 4: Train D touches the ties below it by the dimples, as in step 2.

Step 5: Repeat steps 1 through 4.

COMSOL Simulation of Levitation Trains

For COMSOL simulation, the asymmetric alignment of four trains on the tie can be shown to result in a net force pushing the train to move forward. In this case, the electrical potential of each train can be assumed to be −500 V, −400 V, −300 V, and −200 V, respectively, at step 1. The electrical potential of ties below the trains can have a range from −500V to 100V, for example.

FIG. 7(a) shows the simulation diagram of step 1 in which repulsion from same charges is shown in blue color and attraction from opposite charges is shown in red color. FIG. 7(b) shows the electrical potential of the cross-sectional line in FIG. 7(a). The largest repulsion and the largest attraction can both be shown for Train D. The former can lead to suspension of the train on the tie, and the latter can lead to attraction of the train to the tie in front of it. Therefore, the train can move forward, and the dimples at the bottom of Train D may touch the ties and balance the difference in electrical potential between Train D and the ties.

In step 2, Train D contacts ties and balances the whole electrical potential from the train to the ties, as illustrated in FIG. 7(c) and FIG. 7(d).

In step 3, due to the asymmetry alignment of trains with ties, there is always at least one train car that provides the power to drive the train forward. In FIG. 7(e), when train car D touches the ties, train car A, train car B, and train car C can provide the force to drive the train forward. FIG. 7(f) shows that the strongest repulsion occurs at train car C, and the strongest attraction occurs in front of train car D. The former can suspend the train on the tie again, and the latter can push the train to move forward.

The simulation of step 4 is the same as the one in step 2.

FIG. 7(g) shows a sequence of simulation in steps 1, 2, 3, and 4 for the levitation train. Since there is at least one train car providing the momentum and/or the power for forward motion, the whole levitation train is able to move forward.

Positive Charging Plates

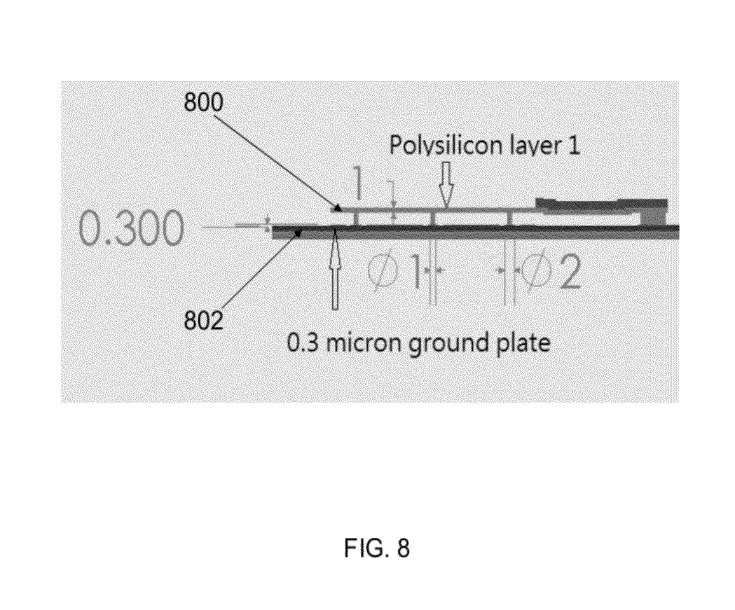

In one embodiment, positive charging plates are used in the I-beam tie levitation train systems to attract the train to move to the desired direction. Positive charging plates can be charged positively by the SEM when scanned. FIG. 8 shows a cross-sectional view of a positive charging plate 800. For an accelerating voltage of the SEM between 12 and 18 keV, penetration depth of incident electrons in polysilicon is more than 1 micron based on FIG. 2. Therefore, for such a voltage, incident electrons will penetrate the one-micron-thick “polysilicon layer 1” and expel initial electrons in the “polysilicon layer 1.” These electrons can enter a ground plate 802 below the “polysilicon layer 1” and result in positively charging effect in the “polysilicon layer 1.”

I-Beam Tie Design

Many different embodiments can be realized based on the I-beam tie design. For example, FIGS. 9(a), 9(b), and 9(c) show a 1 mm I-beam levitation train system. Each tie has two positive charging plates before and behind it, as shown in FIG. 9(d).

FIG. 9(e) is an SEM image of the I-beam levitation train system. The train 902 has a single car in this case. The train 902 may be negatively charged, and suspended over the also negatively-charged I-beam ties 904.

FIG. 9(f) is an SEM image of the I-beam levitation train system including a train 906 having a plurality of cars.

FIG. 9(g) is an SEM image of an I-beam levitation train system including a train 910 having a plurality of cars suspended on I-beam ties 912 arranged in a circular configuration.

1 mm I-Beam Levitation Train

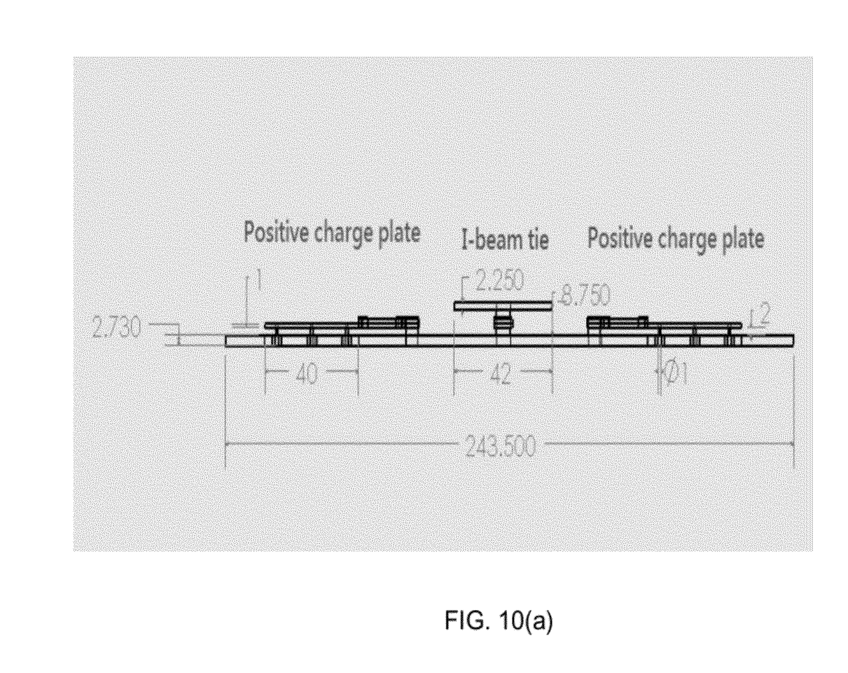

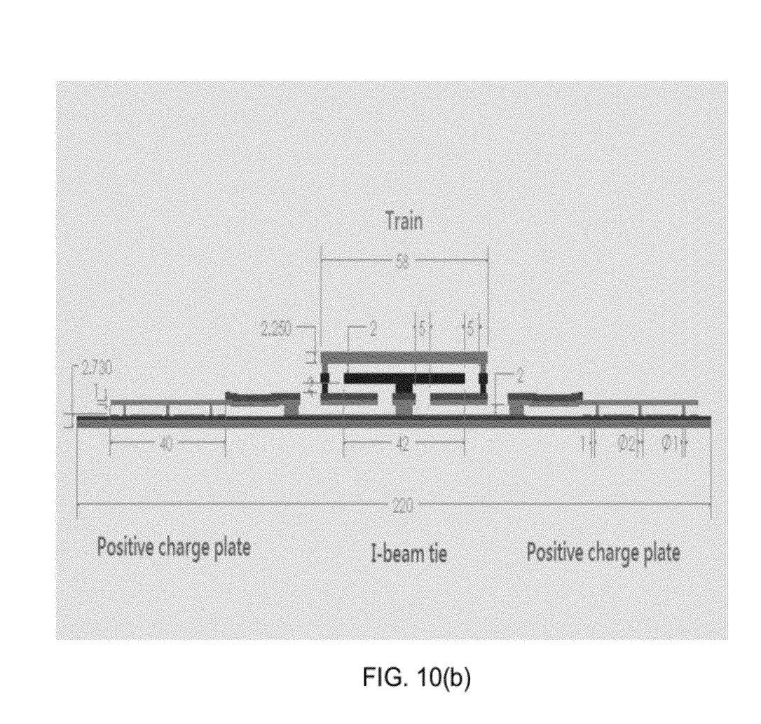

The train can float on the tie due to the Coulombic repulsive forces between negative charges on the train and the I-beam tie below the train, when the train area is scanned by the electron beam. The Coulombic repulsive forces can also drive the train. To guide the train to a desired direction, positive charging plates can be added to the system, as shown in FIG. 9(d). FIGS. 10(a) and 10(b) show front views of the positive charging plates and the trains. The gap between the train and the tie in the horizontal direction is about 5 microns.

This I-beam levitation train in the illustrated example is about 64 micron long, and can move more than 1 mm in each direction. Several variations are described in the following paragraphs.

I-beam Tie in a Circular Loop

I-beam ties can be arranged in series, in circular, or in other configurations.

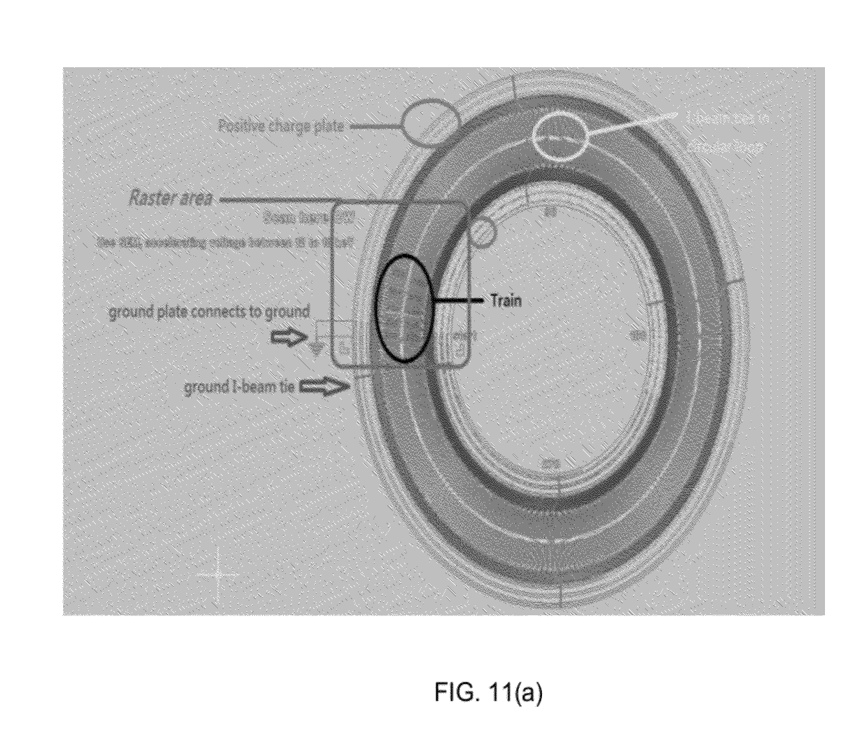

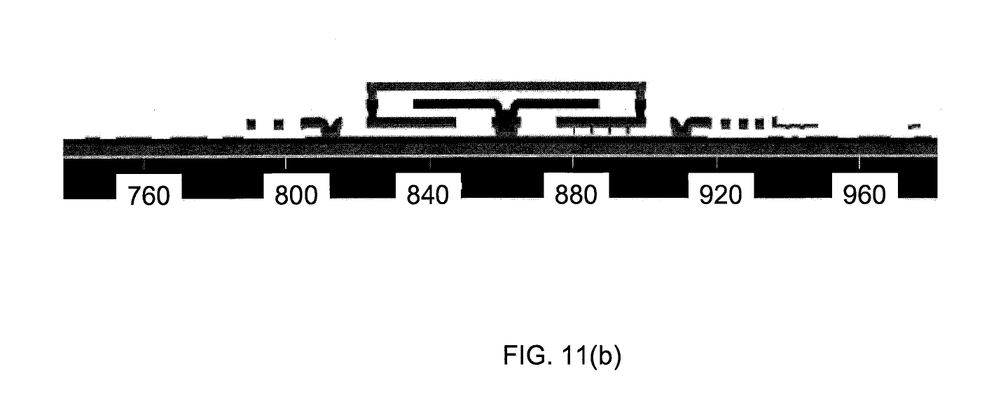

FIG. 11 (a) shows an alternative design for I-beam ties. In this case, the I-beam ties are arranged in a circle, and the train can move in a circular or arc direction. The length of the loop in this illustrated example is about 2236.8 microns.

Charging plates can be located the same way as the I-beam tie on both sides. In this case the train can move in only one direction, counterclockwise. Four I-beam ground ties link ground plates together and enable positive charging to occur in positive charging plates on top of the ground plates. FIG. 11(b) shows the cross-sectional view of the train with the ties at the start point. Some structures such as positive charge plates and the stands of positive charging plates are not shown in this diagram because the ties are not in parallel.

### Levitation Platform

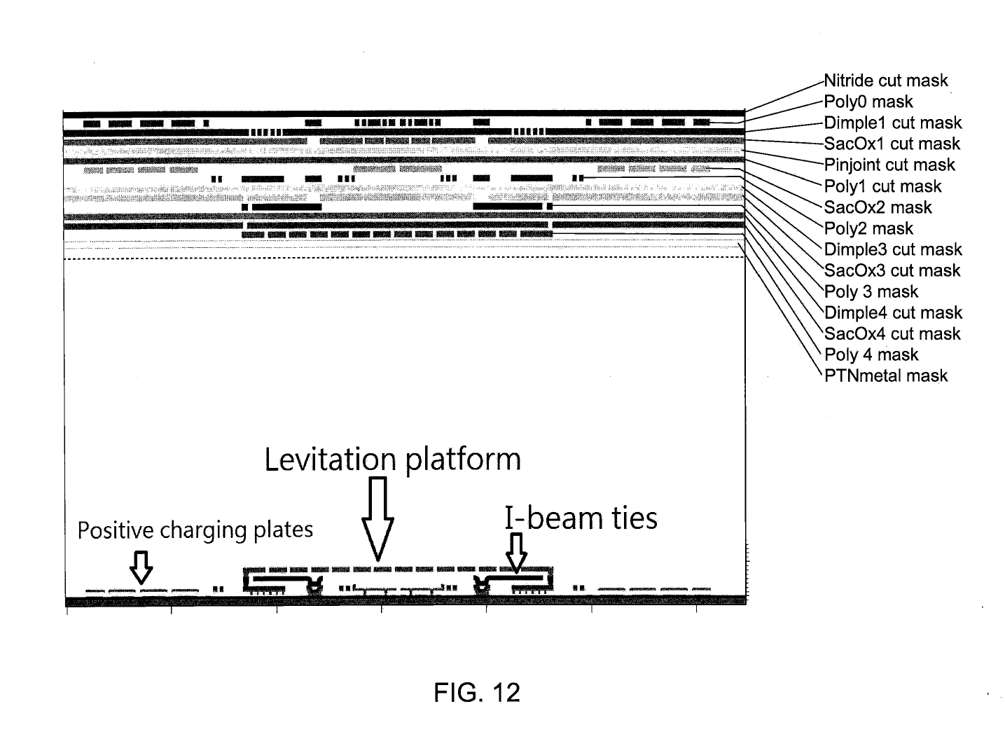

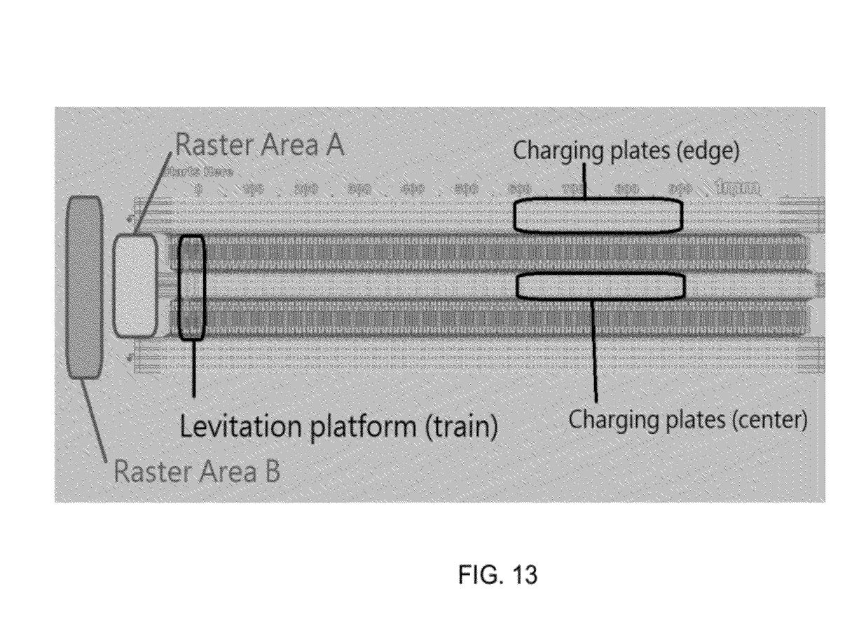

In one embodiment, a levitation platform is provided based on an I-beam levitation train. In FIG. 12, a levitation platform floats on two I-beam ties with four positive charging plates. FIG. 13 shows the structure of the levitation platform. The levitation platform comprises of a big levitation train, two series of I-beam ties and two pairs of positive charging plates. Charging plates at the center of the structure in this illustrative example have a dimension of about 6 by 20 micron, and charging plates at the edge of the structure can have a dimension of about 6 by 60 microns.

This levitation platform can move either forward or backward by changing the raster area of the SEM under the same operation conditions. By scanning raster area A in FIG. 13, the train and the tie below it are negatively charged while the positive charging plates in the center are positively charged. Therefore, the train floats on the tie due to the Coulombic repulsive force, and the positively-charged tie in front of the train attracts the train to move forward due to the Coulombic attractive force. Once the train moves forward, ellipse dimples at the bottom of the train balance the electrical potential difference between the train and the tie. Then, the train and the tie are negatively charged again, and the cycle can be repeated.

For the train to move backward, the raster area B in FIG. 13 is scanned. Since positive charging plates at the edge are about 3 times the size as those at the center, the Coulombic attractive force they generate can be about 3 times that generated by positive charging plates at the center. When the raster area B is scanned, the net attractive force is about twice that when the raster area A is scanned. Therefore, the train will move backward (from the right to the left).

Levitation Trains Based on Electrostatic Microfans

The ties can be arranged into series and in a circular loop to form levitation trains based on electrostatic microfans. Both of them can be actuated by the SEM. The side walls and the upper walls are configured to prevent the train from derailing.

There are several components in this design, for example, trains, ties, upper walls, side walls, ellipse dimples at the bottom of the trains, etc. In one embodiment, positive charging plates are not included because this electrostatic microfan levitation train is suspended and actuated only by Coulombic repulsive force.

Electrostatic Microfan Levitation Train Over Series of Ties

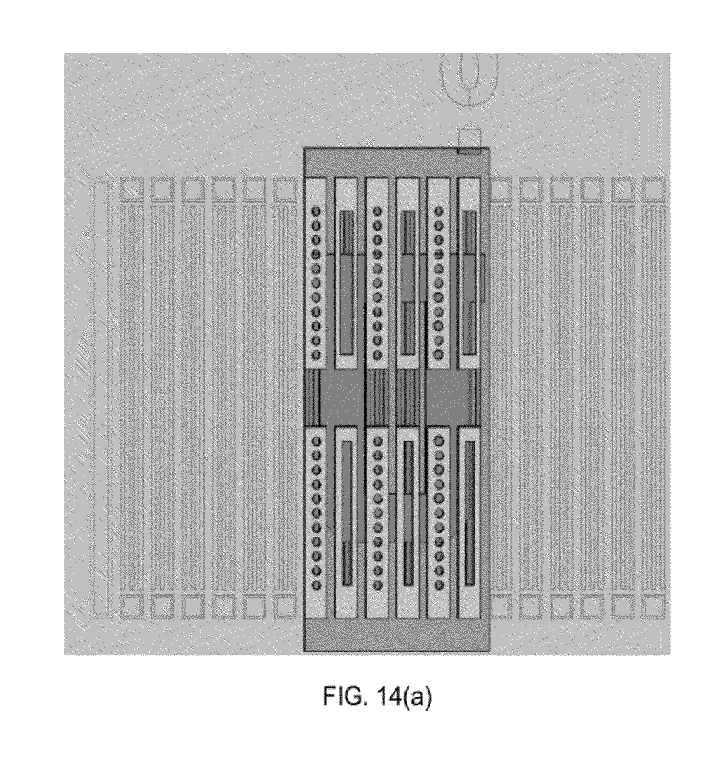

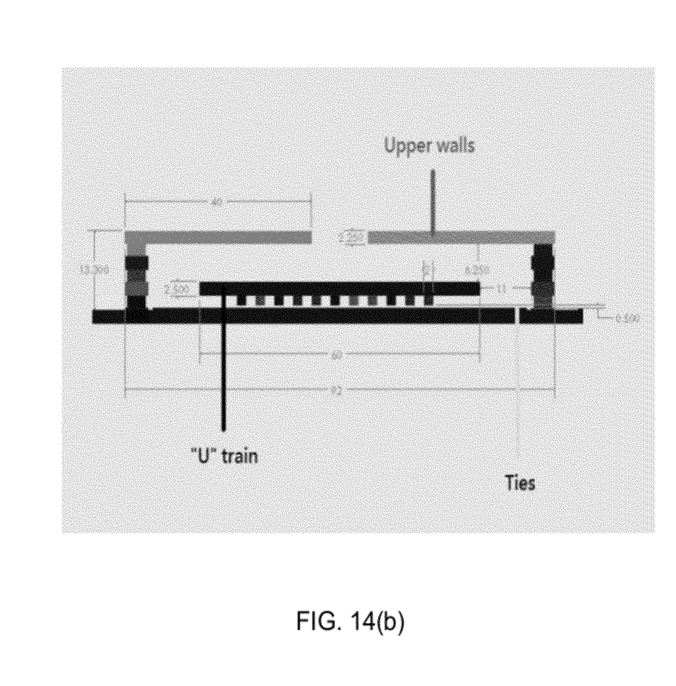

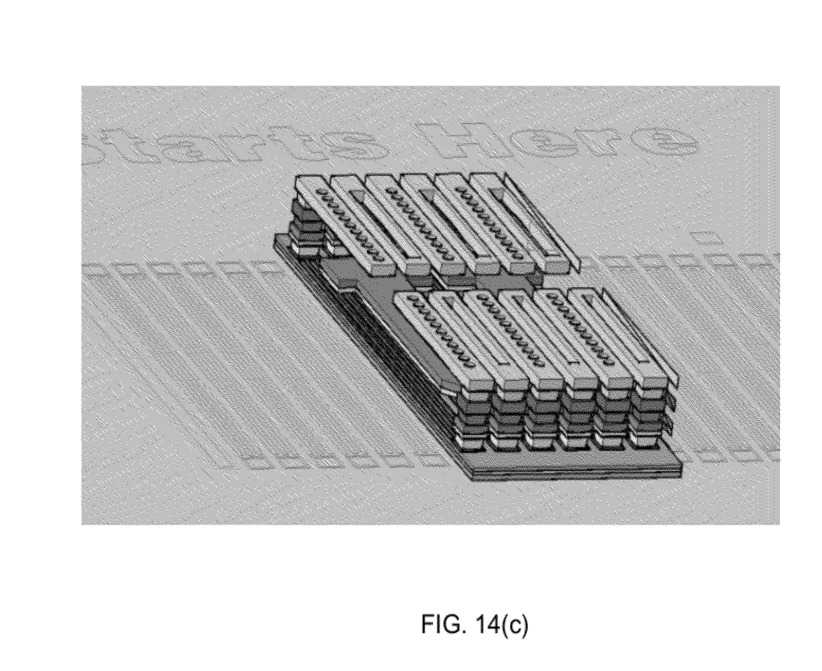

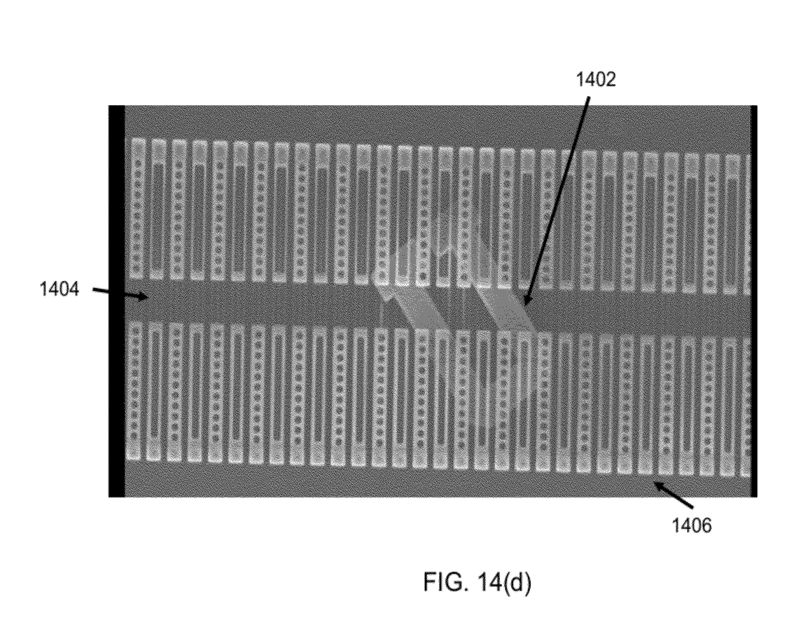

In one illustrative example, a 1200-micron-long track is included in a microfan levitation train system. A U-shaped train is suspended by series of ties. Upper walls and side walls are included to prevent the train from leaving the track. FIGS. 14(a), 14(b), and 14(c) show the structure of this design. Like the I-beam tie system, ellipse dimples at the bottom of the “U” train can help preventing the train from getting stuck in the ties.

FIG. 14(d) is an SEM image of the electrostatic microfan levitation train system. It is noted that the “U”-shaped train 1402 is substantially enclosed by the ties 1404 and the upper walls 1406, and suspended therebetween. The train 1402 can have any other shapes besides the “U” shape. Unlike the I-beam tie system 400 illustrated in FIG. 4, the train 1402 does not substantially enclose a portion of tracks, but rather is suspended between the tracks including the ties 1404 and the upper walls 1406. Thus, although the train 1402 does not have a center axis to rotate about such as that illustrated in FIGS. 5(a) and 5(b), the system shown in FIGS. 14(a)-14(d) is still referred to a “microfan system” to signify that the tracks 1404, 1406 are more extended laterally than the train 1402.

Many other different shaped ties or trains can be employed. For example, an “Ω”-shaped tie can substantially enclose the train, and prevent the train from derailing.

In one embodiment, only one layer of 0.3-micron thick polysilicon is used as the tie. When the system is charged negatively, the ties in the raster area will have more electrostatic energy as compared with the nearby ties; thus, the train may move either forward or backward. On the other hand, the thickness of the “U” train is about 2.5 microns in this illustrative example, with a series of 2.25-micron thick polysilicon walls on top of it.

Holes can be disposed in the upper walls to allow incident electrons to directly pass through upper walls and enter the train, as shown in FIG. 14(c).

Electrostatic Microfan Levitation Train in a Circular Loop of Ties

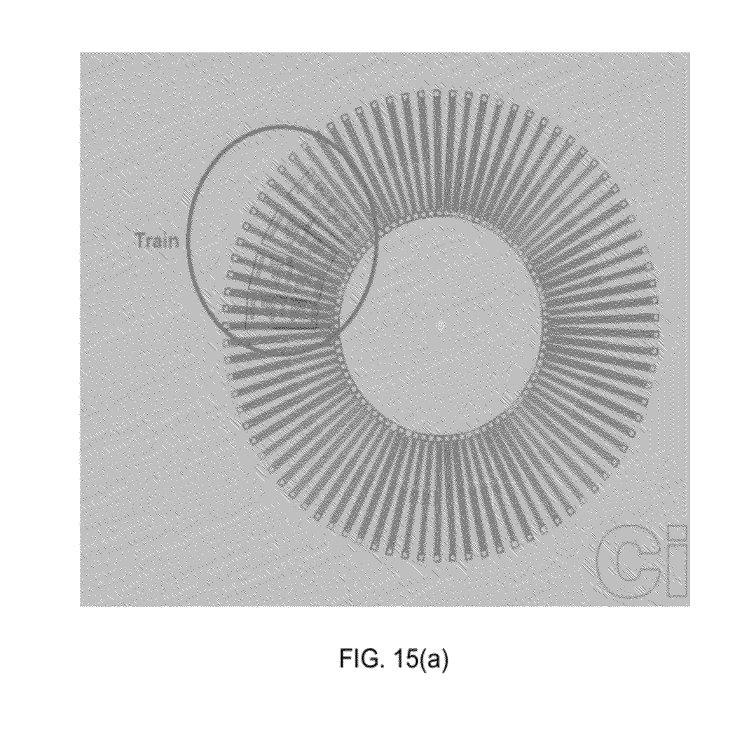

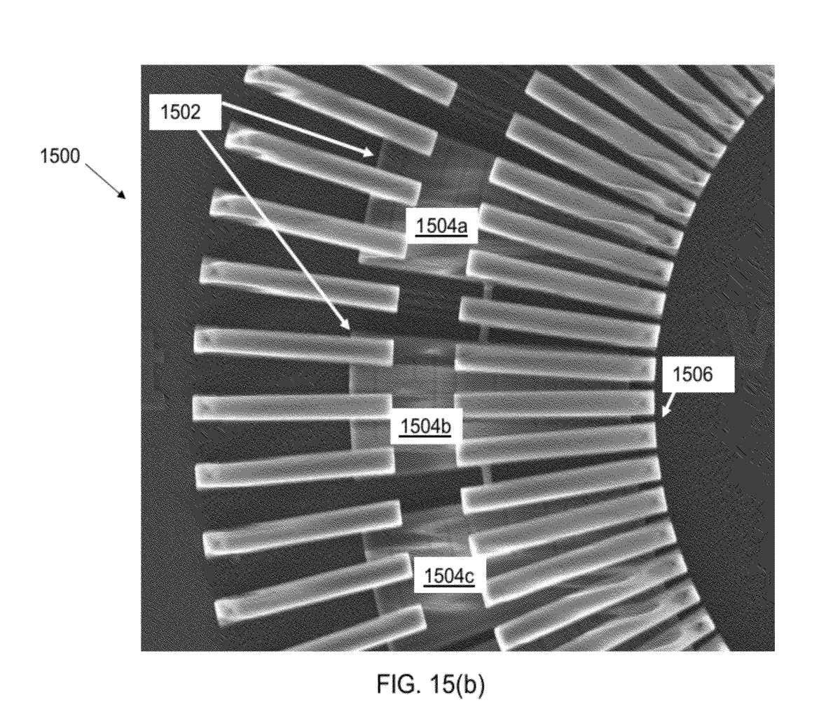

By disposing the ties into the circular loop and making the train to have a slightly arc shape, a circular loop train system can be realized. In the illustrated embodiment, the length of the loop is about 791.6 microns. A series of arc-shaped trains with ellipse dimples are connected together as shown in FIG. 15. Like the design in FIGS. 14(a)-14(c), the train is suspended and actuated by the SEM negative charging forces.

### Operation

By changing the raster areas and the operation conditions of SEM, the levitation trains can be operated to have translational and/or rotational motions.

For I-beam tie systems, control of accelerating voltage may be important because the system can be desirably negatively and positively charged at the same time. In this case, an accelerating voltage between 12 and 18 keV can be used because the penetration depth of the incident electron is smaller than the tie and the train but larger than the positive charging plate. Therefore, incident electrons not only remain in the layer of both the train and the I-beam tie but also penetrate the positive charging plate. This can lead to negative charging effect in both the tie and the train while the positive charging plates are positively charged.

For electrostatic microfan levitation trains, an accelerating voltage less than 18 keV can be used such that the train and the tie may be negatively charged at the same time. An accelerating voltage higher than 18 keV may result in the incident elctrons penetrating the train or tie layers and lead to positive charging effect. Detailed operations of the levitation trains are described in the following sections.

Operation of the 1 mm I-Beam Levitation Train

In certain ranges of accelerating voltages, the SEM can perform negative charging and positive charging effects at the same time in layers with different thickness. If the penetration depth of incident electrons is smaller than the thickness of the layer, the layer can be negatively charged. On the other hand, if there is a ground plate below the layer, the layer can be positively charged when the penetration depth of incident electrons is larger than the thickness of the layer. This is due to that local electrons inside the sample as well as incident electrons from the SEM will leave the sample and enter the ground plate. FIG. 2 shows the penetration depth of incident electrons in polysilicon samples with respect to SEM accelerating voltage. If the accelerating voltage is controlled to be between 12 and 18 keV, incident electrons not only can remain in the 2.25-micron-thick train and the 2.25-micron-thick I-beam tie layers, but also can penetrate and expel local electrons from the 1-micron-thick positive charging plates, as shown in FIG. 10(b).

The moving motion is completed by scanning either raster area A or raster area B in FIG. 9(b) with an accelerating voltage between 12 to 18 keV. For raster area A, positive charging plates at the right side of the tie can provide a positive potential in the ties on the ride side the train, and therefore attract the negatively-charged train to move to the right (forward). On the other hand, for scanning raster area B, positive charging plates will produce positive-potential ties at the left side of the train, and thus attract the train to move to the left.

Operation of I-beam Levitation Train in Circular Loop Tie

Since positive charging plates are at the same direction of the I-beam ties at each side, as shown in FIG. 11(a), the train can only move in one direction. Because positive charging plates at the left side is below the tie and in front of the tie at the right side, the train can move counterclockwise when the raster area in FIG. 11(a) is scanned counterclockwise. The accelerating voltage used here can be the same as that in the 1 mm levitation train.

Operation of the Levitation Platform

FIG. 13 shows a levitation platform comprising two I-beam tie rails and four series of positive charging plates. Because the area of positive charging plates at the center of the structure is about ⅓ of those at the edge of the structure, the Coulombic attractive force generated by the plates at the center is about ⅓ that at the edge. Based on this feature, if the raster area A in FIG. 13 is scanned, the train can move forward. If the raster area B in FIG. 13 is scanned, the train can move backward. The accelerating voltage used here can be the same as that used in the 1 mm levitation train.

Operation of Electrostatic Microfan Levitation Trains

An accelerating voltage of less than 18 keV can be used to prevent positive charging effects in either the 2.5-micron-thick train or the ties in the electrostatic microfan levitation train systems.

Operation of the Electrostatic Microfan Levitation Train In Series

These electrostatic microfan levitation trains can be suspended and actuated purely from negative charge repulsive forces. Thus, the operation can be simpler than that of the I-beam train systems.

Negative charging effect can be used to suspend and actuate the train. Because the thickness of the train is about 2.5 microns, an SEM accelerating voltage of less than 18 keV can be used to prevent penetration of incident electrons in the train layers.

The train can move at the same direction of the route of raster area. For example, when the user scans and focuses the starting points, the train, the upper walls and the ties can be negatively charged at the same time, and this electrical field can lead the train to move either to the right or the left. When the user slowly moves the raster area to the left, the train can be forced to move to the left to reach the electrical balance between the dimple and the tie. As such, the direction of train movement can be controlled.

Operation of the Electrostatic Microfan Levitation Trains in a Circular Loop

As shown in FIG. 15(a), when an accelerating voltage of less than 18 keV is applied, the train can be suspended by the tie and move clockwise or counterclockwise because the penetration depth of incident electrons is smaller than the 2.5-micron-thick train.

FIG. 15(b) is an SEM image of a electrostatic microfan levitation train system 1500. The train 1502 includes a plurality of cars 1504a, 1504b, 1504c, . . . , coupled together and arranged over a circular loop of ties 1506.

Levitation Train System with Smoothed Edge Portions

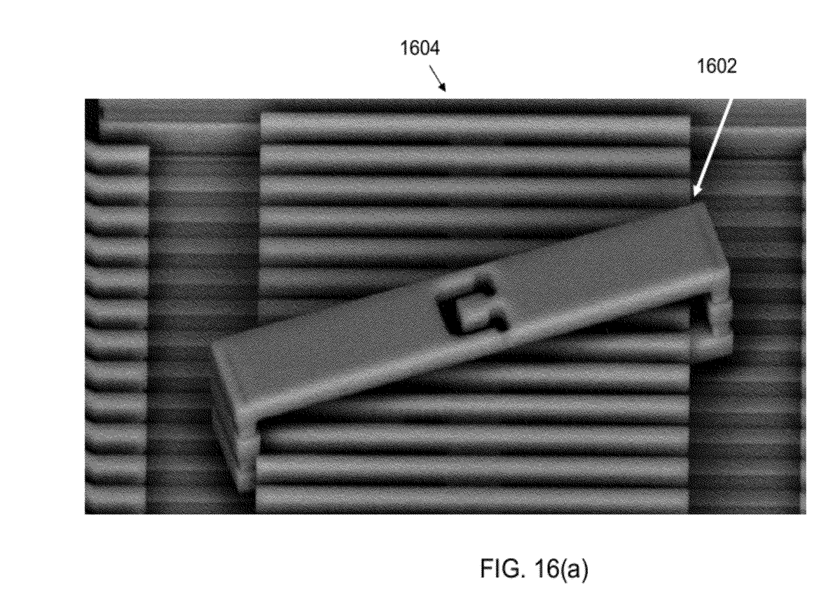

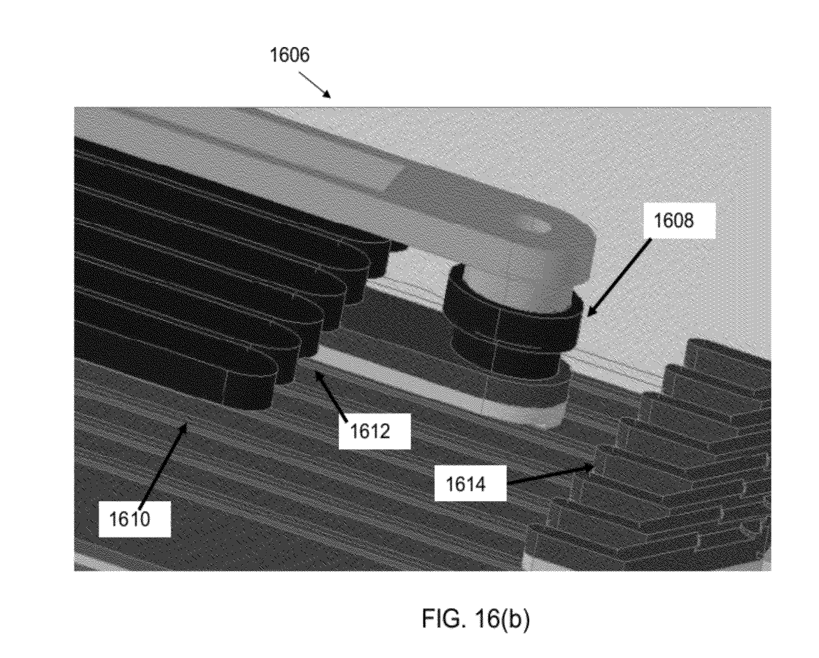

FIG. 16(a) is an SEM image of a single-car I-beam levitation train system in an misaligned position. That is, rather than having a train 1602 substantially aligned with the track 1604 and move linearly thereabout, in some cases the train 1602 may rotate for a small angle relative to the track 1604, and become stuck with the ties.

FIG. 16(b) is a schematic diagram of an I-beam levitation train system including smoothed edged portions configured to avoid the train being stuck on the track. For example, the train 1606 can have a smoothed edge portion 1608, which as illustrated can have a substantially circular shape. Similarly, the track 1610 can also have smoothed or round edge portions 1612, 1614. Thus, even if the edge portions of the train 1606 come into contact with the edge portions of the track 1610, due to their smooth surfaces, the possibility for the train 1606 to be stuck on the track 1610 is significantly reduced.

Summary of Some of the Embodiments and Advantages

A MEMS device is configured to be actuated directly by an energy field through Coulombic interactions to have a translational motion. The translational motion can be a linear motion or a circular motion. For example, the MEMS device is configured to be suspended over a rail by the Coulombic interactions during the translational motion.

A charge collection element can be used to build up electrical charges by directly interacting with the energy field. The energy field can interact with the actuator through free space propagation.

The MEMS device therefore provides an untethered vehicle configured to have the translational motion. The energy field can include at least one of an electron beam, a laser beam, a radiation beam, a charged particle beam, an uncharged particle beam, a photon beam, a static charge from triboelectric effect, or a discharge of a capacitor. For example, the energy field comprises an electron beam from an SEM, and the electron beam causes electrical charges to build up on a charge collection element of the MEMS device.

In some embodiment, the MEMS device is configured as a carrying device. In some other embodiments, the MEMS device is configured as a sensor.

The MEMS device can have a rail and a suspension portion, wherein the rail and the suspension portion include a geometric shape to prevent the suspension portion from derailing.

In some embodiments, the untethered MEMS device comprises a charge collection element configured to actuate the untethered MEMS device through Coulombic interactions when subject to an energy field. The energy field can comprise an electron beam. The Coulombic interactions can include at least one of a repulsive interaction or an attractive interaction. The Coulombic interactions are configured to suspend and move a movable portion over a rail.

In some embodiments, the movable portion and the rail include a “U” shape or an “Ω” shape to allow the movable portion move along the rail in a translational motion without derailing.

In some embodiments, the untethered MEMS device is configured as a sensor to sense a property of an energy field that actuates the untethered MEMS device to have the translational motion. In some other embodiments, the untethered MEMS device is configured as a carrying device to deliver an agent to a location.

To actuate the MEMS) device, a method is provided including irradiating an actuator of the MEMS device with an energy field thereby building up electrical charges on the actuator; and actuating the MEMS device with Coulomb forces from the built up electrical charges to suspend a movable portion over a rail and drive the movable portion along the rail in a translational motion.

In one embodiment, the energy field is irradiated onto the actuator through free space propagation. Said actuating the MEMS device with Coulomb forces comprises actuating the MEMS device with a combination of repulsive and attractive Coulombic interactions.

In one embodiment, the method further includes observing the translational motion using the SEM. In another embodiment, the method further includes observing the translational motion using an optical microscope.

The train can be used to deliver an agent such as a chemical along the rail.

In some embodiments, the method further includes measuring the translational motion. The method can further comprise deriving a property of the energy field based on the observed translational motion. The rail can be configured as a linear rail or a circular rail.

Embodiments disclosed herein include design concepts and actuation mechanisms of several SEM-actuated levitation trains. Electrostatic repulsive and attractive forces between train carriages (cars) and ties of the tracks are used to suspend and guide the trains. In one example, the train is built from five-layer polysilicon, with a maximum thickness of about 13.6 microns while each layer is no more than 2.25 micron thick. The movement range of the train can be at least 1 mm in each direction.

These levitation trains can be divided into two categories: I-beam tie systems and electrostatic micro-fan systems. The former comprises I-beam tie series with a floating “Ω”-shaped train. The latter comprises of a series of tie with a floating “U” shape train constrained in walls based on the concept of a micro-fan actuated by electrostatic repulsive force between the fin and the rails. For both designs, when applying a given range of SEM accelerating voltage to raster the actuation area in the systems, incident electrons can stay in both the train carriages and the ties and negatively charged them; thus, train carriages are suspended on the ties. In some systems, additional positive charging plates connecting to the ties provide attraction force in a desired direction.

Advantageously, embodiments of disclosed herein provide a non-contact and non-intrusive method of actuating MEMS devices. High displacement, in-plane (rotational and linear) and out-of-plane motions can be realized using one or both of attraction- or repulsion-driven electrostatic drives, through charge pumping. The resulting MEMS devices can be untethered, e.g., not fixed to a certain geometrical location, but rather can move freely. In the case when an electron beam from an SEM is used for charge pumping, visualization of MEMS device operation can be achieved at the same time of operating such devices thereby providing an in situ examination for the designs. These MEMS devices can function as actuators and/or sensors.

In some embodiments, the MEMS device disclosed herein can be used not only as a delivery or carrying device such as a “train,” but can also be used as a sensor. For example, if the “train” senses the energy field such as the electron beam, the “train” can be actuated to have a linear (or circular) motion. The motion translates into a travel distance or a speed, which can be measured through an optical microscope, an SEM, or any other suitable measurement instruments. Thus, the “train” acts as a sensor to sense the strength, location, or other properties of the energy field.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. All of the publications, patent applications and patents cited herein are incorporated herein by reference in their entirety.

What is claimed is:

1. A microelectromechanical system (MEMS) levitation device comprising:
a movable portion; and
a track,
wherein the movable portion is configured to be actuated directly by an energy field through Coulombic interactions to have a translational motion over the track.

2. The MEMS device of claim 1, wherein the translational motion comprises at least one of a linear motion or a circular motion.

3. The MEMS device of claim 1, wherein the movable portion is configured to be suspended over the track by the Coulombic interactions during the translational motion.

4. The MEMS device of claim 1, comprising a charge collection element coupled to the track and configured to build up electrical charges by directly interacting with the energy field.

5. The MEMS device of claim 1, wherein the energy field interacts with the actuator through free space propagation.

6. The MEMS device of claim 1, wherein the movable portion is untethered.

7. The MEMS device of claim 1, wherein the energy field comprises at least one of an electron beam, a laser beam, a radiation beam, a charged particle beam, an uncharged particle beam, a photon beam, a static charge from triboelectric effect, or a discharge of a capacitor.

8. The MEMS device of claim 7, wherein the energy field comprises an electron beam from a scanning electron microscope (SEM).

9. The MEMS device of claim 1, wherein the MEMS device is configured as a carrying device or a sensor.

10. The MEMS device of claim 1, wherein the movable portion substantially encloses at least a portion of the track to thereby prevent the movable portion from derailing from the track.

11. The MEMS device of claim 10, wherein the movable portion is configured to be levitated over the track and actuated through positive and negative charges generated from the energy field.

12. The MEMS device of claim 11, wherein the movable portion comprises a plurality of carriages, wherein at least one carriage is configured to be actuated to have the translational motion while at least another carriage is configured to contact the track to balance an electrical potential.

13. The MEMS device of claim 1, wherein the track substantially encloses at least a portion of the movable portion to thereby prevent the movable portion from derailing from the track.

14. The MEMS device of claim 13, wherein the movable portion is configured to be both levitated over the track and actuated only through negative charges generated from the energy field.

15. The MEMS device of claim 1, wherein at least a portion of the movable portion and a portion of the track have smoothed surfaces to avoid the movable portion being stuck with the track.

16. The MEMS device of claim 15, wherein the smoothed surfaces include substantially circular shapes.

17. A levitation system comprising:
a microelectromechanical system (MEMS) device including:
a train; and
a track,
wherein the train is not tethered to the track, and
a scanning electron microscope (SEM),
wherein the SEM is configured, using an electron beam, to directly levitate the train over the track and actuate the train to have a translational motion about the track through Coulombic interactions.

18. The levitation system of claim 17, wherein the MEMS device further comprises a plurality of charge collection elements configured to generate electrical charges when illuminated with the electron beam to realize the Coulombic interactions between the train and the track.

19. The levitation system of claim 17, wherein the train and the track include:
a first geometric shape configured to prevent the train from derailing from the track; and
a second geometric shape configured to prevent the train from becoming stuck with the track.

20. A method of actuating a microelectromechanical system (MEMS) device, comprising:
irradiating an actuator of the MEMS device with an electron beam from a scanning electron microscope (SEM) thereby building up electrical charges on the actuator; and
actuating the MEMS device with Coulomb forces from the built up electrical charges to suspend a movable portion over a rail and drive the movable portion along the rail in a translational motion.

21. The method of claim 20, wherein said actuating comprises raster-scanning a portion of the rail.

22. The method of claim 20, further comprising observing the translational motion using the SEM at the same time of said actuating.
